(19) United States
(12) Patent Application Publication
(10) Pub. No.: US 2025/0094540 A1
(43) Pub. Date: Mar. 20, 2025

(54) APPARATUS, METHOD, AND COMPUTER PROGRAM FOR DETERMINING NORMALCY OF DATA OF DIGITAL TWIN MODEL

(71) Applicant: STANS INC., Seoul (KR)

(72) Inventors: Ji Hye JEON, Seoul (KR); Jong Ho BAIK, Namyangju-si Gyeonggi-do (KR); Seung Hyun LEE, Seoul (KR)

(73) Assignee: STANS INC., Seoul (KR)

(21) Appl. No.: 18/956,262

(22) Filed: Nov. 22, 2024

Related U.S. Application Data
(63) Continuation of application No. PCT/KR2023/004080, filed on Mar. 28, 2023.

(30) Foreign Application Priority Data
May 23, 2022 (KR) 10-2022-0062777

(51) Int. Cl. G06F 18/20

(52) U.S. Cl. CPC G06F 18/285

(57) ABSTRACT

A data normality determination apparatus that determines whether data of a digital twin model is normal includes a reference value setting unit configured to set a reference value for a sensor selected from among a plurality of sensors connected to the digital twin model; an analysis unit configured to compare and analyze real-time sensor data measured by the selected sensor with the reference value; a determination unit configured to determine whether the real-time sensor data is normal based on a result of the analysis; and an output unit configured to output a result of determining whether the real-time sensor data is normal.

### CROSS-REFERENCE TO RELATED APPLICATIONS

This application is a continuation of International Application No. PCT/KR2023/004080 filed on Mar. 28, 2023, which claims priority to Korean Patent Application No. 10-2022-0062777 filed on May 23, 2022, the entire contents of which are herein incorporated by reference.

### TECHNICAL FIELD

The present disclosure relates to an apparatus, method and computer program for determining whether data of a digital twin model is normal.

### BACKGROUND

A digital twin refers to a technology that creates a virtual counterpart in a computer to correspond to an object in a real world and simulating situations that may occur in the real world using the computer, to predict results in advance. The digital twin is a digital entity that can be used to optimize the physical world, and is attracting attention as a technology that can significantly improve operational performance and business processes, thereby addressing various problems in industrial and social fields as well as in a manufacturing field.

The digital twin is a technique that integrates a large number of sensors and big data. The digital twin provides a manager with information on whether data measured by sensors is normal and thus helps the manager in determining the situation.

Meanwhile, conventional search algorithms for digital twin use continuous or discrete variables to search for information stored in certain data structures or to perform computation in a search space of a problem domain.

However, these conventional search algorithms require a significant amount of time to search for whether measured data of sensors desired by the manager falls within a normal range and perform calculation.

### SUMMARY OF THE INVENTION

### Problems to be Solved by the Invention

In view of the foregoing, the present disclosure is conceived to compare and analyze a reference value for a sensor selected from a plurality of sensors connected to a digital twin model with real-time sensor data measured by the selected sensor and determine whether the real-time sensor data is normal.

Also, the present disclosure is conceived to output and provide a result of determining whether the real-time sensor data is normal.

However, the problems to be solved by the present disclosure are not limited to the above-described problems. There may be other problems to be solved by the present disclosure.

### Means for Solving the Problems

According to at least one example embodiment, a data normality determination apparatus that determines whether data of a digital twin model is normal may include a reference value setting unit configured to set a reference value for a sensor selected from among a plurality of sensors connected to the digital twin model; an analysis unit configured to compare and analyze real-time sensor data measured by the selected sensor with the reference value; a determination unit configured to determine whether the real-time sensor data is normal based on a result of the analysis;
and an output unit configured to output a result of determining whether the real-time sensor data is normal

According to at least one other example embodiment, a method for determining whether data of a digital twin model is normal, which is performed by a data normality determination apparatus, may include setting a reference value for a sensor selected from among a plurality of sensors connected to the digital twin model; comparing and analyzing real-time sensor data measured by the selected sensor with the reference value; determining whether the real-time sensor data is normal based on a result of the analysis; and outputting a result of determining whether the real-time sensor data is normal.

According to at least one other example embodiment, a computer-readable medium storing a computer program including a sequence of instructions to determine whether data of a digital twin model is normal, which when executed by a computing device, causes the computing device to: set a reference value for a sensor selected from among a plurality of sensors connected to the digital twin model; compare and analyze real-time sensor data measured by the selected sensor with the reference value; determine whether the real-time sensor data is normal based on a result of the analysis; and output a result of determining whether the real-time sensor data is normal.

This summary is provided by way of illustration only and should not be construed as limiting in any manner. Besides the above-described exemplary embodiments, there may be additional exemplary embodiments that become apparent by reference to the drawings and the detailed description that follows.

### Effects of the Invention

According to any one of the above-described means for solving the problems of the present disclosure, it is possible to compare and analyze a reference value for a sensor selected from a plurality of sensors connected to a digital twin model with real-time sensor data measured by the selected sensor and determine whether the real-time sensor data is normal.

Further, according to the present disclosure, it is possible to output and provide a result indicating whether the real-time sensor data is normal.

Therefore, according to the present disclosure, it is possible to provide a service that quickly searches for whether real-time sensor data of a sensor that a manager wants to check falls within a normal range.

Furthermore, according to the present disclosure, visualized information on whether the real-time sensor data of the sensor falls within the normal range is provided to the manager, and, thus, the manager can quickly identify the type of disaster occurring in a building equipped with the sensor and receive help to take initial response actions based on the identified type of disaster.

### BRIEF DESCRIPTION OF THE DRAWINGS

FIG. 1 is a block diagram of a data normality determination apparatus according to an embodiment of the present disclosure.

FIG. 2 shows an example of a digital twin model according to an embodiment of the present disclosure.

FIG. 3A is an example of setting reference values for sensors according to an embodiment of the present disclosure. FIG. 3B is another example of setting reference values for sensors according to an embodiment of the present disclosure.

FIG. 4 is a flowchart showing a method for determining whether data of the digital twin model is normal according to an embodiment of the present disclosure.

### DETAILED DESCRIPTION OF THE INVENTION

Hereafter, example embodiments will be described in detail with reference to the accompanying drawings so that the present disclosure may be readily implemented by those skilled in the art. However, it is to be noted that the present disclosure is not limited to the example embodiments but can be embodied in various other ways. In the drawings, parts irrelevant to the description are omitted for the simplicity of explanation, and like reference numerals denote like parts through the whole document.

Throughout this document, the term “connected to” may be used to designate a connection or coupling of one element to another element and includes both an element being “directly connected” another element and an element being “electronically connected” to another element via another element. Further, it is to be understood that the terms “comprises,” “includes,” “comprising,” and/or “including” means that one or more other components, steps, operations, and/or elements are not excluded from the described and recited systems, devices, apparatuses, and methods unless context dictates otherwise; and is not intended to preclude the possibility that one or more other components, steps, operations, parts, or combinations thereof may exist or may be added.

Throughout this document, the term “unit” may refer to a unit implemented by hardware, software, and/or a combination thereof. As examples only, one unit may be implemented by two or more pieces of hardware or two or more units may be implemented by one piece of hardware.

Throughout this document, a part of an operation or function described as being carried out by a terminal or device may be implemented or executed by a server connected to the terminal or device. Likewise, a part of an operation or function described as being implemented or executed by a server may be so implemented or executed by a terminal or device connected to the server.

Hereinafter, embodiments of the present disclosure will be explained in detail with reference to the accompanying drawings or flowchart.

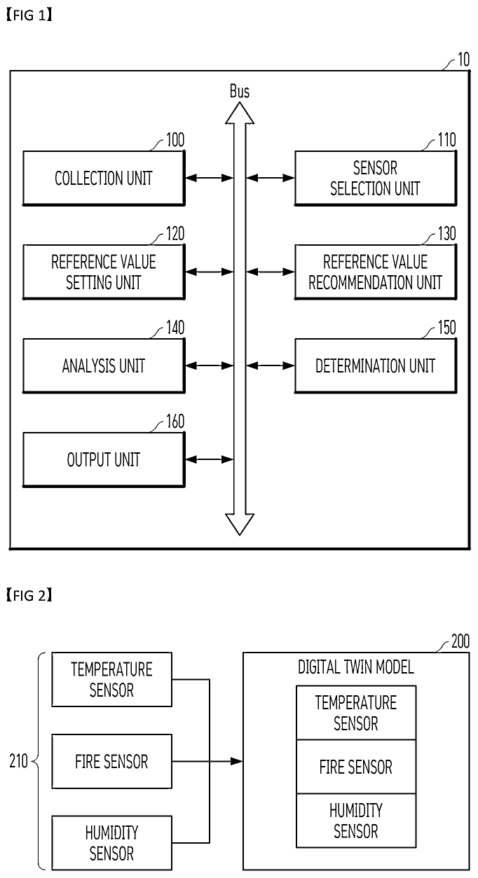

FIG. 1 is a block diagram of a data normality determination apparatus according to an embodiment of the present disclosure.

Referring to FIG. 1, a data normality determination apparatus 10 may include a collection unit 100, a sensor selection unit 110, a reference value setting unit 120, a reference value recommendation unit 130, an analysis unit 140, a determination unit 150, and an output unit 160. The data normality determination apparatus 10 may include one or more processors and one or more memory modules storing programs. The collection unit 100, the sensor selection unit 110, the reference value setting unit 120, the reference value recommendation unit 130, the analysis unit 140, the determination unit 150, and the output unit 160 may be program modules in the form of operating systems, application program modules, and other program modules stored in the memory modules. Such program modules may include, but are not limited to, routines, subroutines, programs, objects, components, and data structures for performing specific tasks or executing specific abstract data types according to the invention as will be described below. However, the data normality determination apparatus 10 illustrated in FIG. 1 is merely an embodiment of the present disclosure, and various modifications may be made based on the components illustrated in FIG. 1.

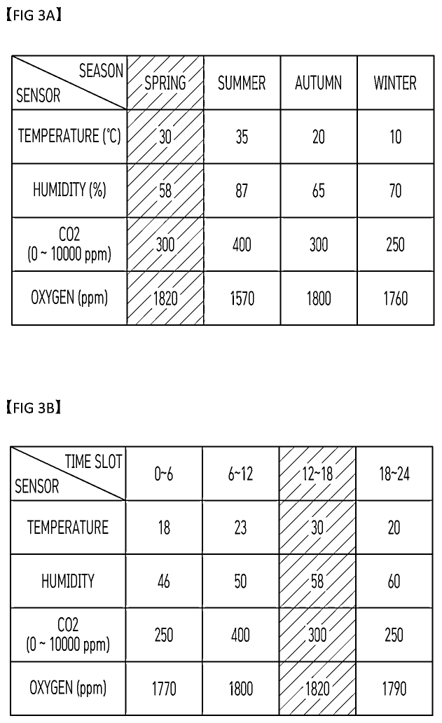

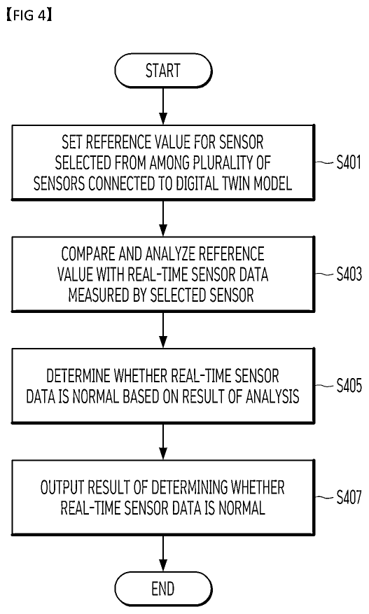

Hereafter, FIG. 1 will be described with reference to FIG. 2 to FIG. 3B.

A digital twin model refers to a technology that creates a virtual counterpart in a computer to correspond to an object in a real world and simulating situations that may occur in the real world using the computer to predict results in advance. For example, the digital twin model may be a model which enables simulation of disaster situations for each type of disaster that can happen in an underground utility tunnel.

The digital twin model will be described briefly. The digital twin model may be a model which enables prediction or simulation of the occurrence of a specific event related to disasters (e.g., fire, flood, earthquake, and the like) in a target area to be managed, such as an underground utility tunnel. Referring to FIG. 2, a digital twin model 200 may be mapped to a plurality of sensors 210 installed in the underground utility tunnel, which serves as a target area to be managed. The digital twin model may receive sensor data collected from the plurality of sensors 210 mapped to the digital twin model and predict or simulate the occurrence of a specific event.

According to the present disclosure, it is possible to determine whether data of the digital twin model is normal in order to predict or simulate the occurrence of a specific event through the digital twin model.

Specifically, the collection unit 100 may collect sensor data from a plurality of sensors connected to respective digital twin models corresponding to a plurality of target areas to be managed, and store the sensor data collected from the sensors for the plurality of digital twin models in a database.

For example, the collection unit 100 may collect sensor data from the plurality of sensors 210 (e.g., a temperature sensor, a fire sensor, and a humidity sensor) connected to the digital twin model 200 for a target area to be managed, and store the sensor data collected in a database of each sensor.

The sensor selection unit 110 may receive input of a digital twin model for a target area to be managed from the manager among a plurality of digital twin models.

The sensor selection unit 110 may select one of the plurality of sensors 210 connected to the digital twin model 200 for a target area to be managed under control of the manager. Herein, the plurality of sensors may include, for example, an environment sensor, an image sensor, a voice sensor, a vibration sensor, and the like. Herein, the environment sensor may include, for example, a temperature sensor, a humidity sensor, a fire sensor (e.g., a flame sensor, a smoke sensor, a CO₂ sensor, a CO sensor, an O₂ sensor, a NO₂ sensor, an H₂₅ sensor, etc.), and the like. Also, the image sensor may include a thermal imaging sensor, a low light image sensor, and the like. The measurement units differ for each of the plurality of sensors. For example, as for the temperature sensor, the measurement unit may be set in Celsius, and as for the humidity sensor, the measurement unit may be set in percentage.

Since the measurement units differ for each sensor, it is not easy to manage the sensor data collected from the sensors in an integrated manner. To solve this problem, the present disclosure requires operations to automatically normalize a difference between a reference value set for each sensor and sensor data collected from each sensor by setting a different reference value for each sensor.

The reference value setting unit 120 may set a reference value (or normal range information) for each sensor to determine whether each sensor is operating normally.

Specifically, the reference value setting unit 120 may set a reference value for a sensor selected by the manager from among the plurality of sensors 210 connected to the digital twin model 200. Herein, the reference value may include at least one of seasonal reference values and time-based reference values.

For example, referring to FIG. 3A, when the sensors selected by the manager are temperature, humidity, CO₂ and oxygen sensors, the reference value setting unit 120 may set seasonal reference values corresponding to spring, summer, autumn, and winter according to the measurement units for the selected sensors under control of the manager. For another example, when the reference value setting unit 120 sets a reference value corresponding to one season under control of the manager, a reference value corresponding to another season can be automatically set by analyzing a difference in average sensing data value between seasons.

For yet another example, when the reference value setting unit 120 sets values corresponding to the respective seasons while generating a table (e.g., a table shown in FIG. 3A or FIG. 3B) containing sensing data information for each sensor, the reference value setting unit 120 may automatically set reference values corresponding to the respective seasons based on average sensing data for each season and a difference in average sensing data value between seasons.

For example, referring to FIG. 3B, when the sensors selected by the manager are temperature, humidity, CO₂ and oxygen sensors, the reference value setting unit 120 may set a reference value corresponding to a first time slot (00:00 to 06:00), a reference value corresponding to a second time slot (06:00 to 12:00), a reference value corresponding to a third time slot (12:00 to 18:00), and a reference value corresponding to a fourth time slot (18:00 to 24:00) according to the measurement units for the selected sensors under control of the manager.

The reference value setting unit 120 may further set error margin information based on the reference values for the selected sensors.

For example, when a reference value for the humidity sensor is set to 30%, the reference value setting unit 120 may also set error margin information for the reference value including −5 to +5 under control of the manager.

When the reference value set by the manager for the sensor does not fall within a normal range for sensor data of a sensor which operates in a normal environment, the reference value setting unit 120 may provide the manager with guidance information for setting a reference value for the sensor as well as a warning message indicating that the set reference value is inappropriate.

The reference value recommendation unit 130 may analyze pattern information based on sensor data previously collected from the selected sensor (i.e., sensor data stored in a database of the selected sensor), derive a reference value for the selected sensor based on the analyzed pattern information, and recommend the derived reference value as a reference value for the sensor selected by the manager. Herein, the pattern information may be an average value obtained by averaging sensor data previously collected from the selected sensor. For example, the reference value recommendation unit 130 may classify the pre-collected sensor data according to predetermined periods, derive upper and lower average limits for the classified sensor data by period, derive a periodic reference value corresponding to an average value of the upper and lower average limits derived from the derived upper and lower average limits, and recommend the derived periodic reference value to the manager.

The reference value recommendation unit 130 may analyze a similarity between a plurality of digital twin models and a digital twin model selected by the manager, and select a similar digital twin model from the plurality of digital twin models based on the analyzed similarity. For example, the similarity may be analyzed based on a correlation coefficient derived between data of different digital twin models. Herein, as the correlation coefficient increases, the similarity also increases.

Then, the reference value recommendation unit 130 may extract a reference value, which is previously set for at least one sensor associated with the selected similar digital twin model, from a reference value table and recommend the extracted reference value to the manager as a reference value for the sensor selected by the manager. Herein, the reference value table may store reference values (reference values previously set by another manager) set for each sensor connected to each digital twin model.

When the manager selects the reference value for the sensor recommended to the manager by the reference value recommendation unit 130, the reference value setting unit 120 may set the reference value selected by the manager as a reference value for the sensor.

Meanwhile, whenever a specific sensor is selected by the manager, a reference value for the sensor may be set differently and an absolute value of a difference between sensor data of the sensor and the reference value for the sensor may be derived differently. If there is a history in which reference values have been set for the selected sensor, the reference value recommendation unit 130 may analyze an absolute value of a difference between sensor data of the sensor and reference values for the sensor, select an ideal reference value from among reference values for the sensor based on a result of the analysis, and recommend the selected reference value to the manager as a reference value for the sensor. For example, the reference value recommendation unit 130 may derive an absolute value of a difference between sensor data of a sensor and reference values for the sensor, derive a standard deviation value of absolute values for the plurality of reference values, and recommend, to the manager, a reference value corresponding to the lowest absolute value from the derived standard deviation value of the plurality of absolute values.

The reference value setting unit 120 may derive a feedback factor from the absolute value of a difference between the sensor data of the selected sensor and the reference value for the selected sensor, and adjust the reference value for the sensor based on the derived feedback factor. For example, when a plurality of absolute values for a difference between the sensor data of the sensor and the reference value for the sensor is collected for a predetermined period of time, the reference value setting unit 120 may determine whether the plurality of collected absolute values exceeds a predetermined threshold, and determine a reference value, which does not exceed the predetermined threshold, by using a result of the determination as the feedback factor.

The reference value setting unit 120 may also set normal range information for the sensor selected by the manager from among the plurality of sensors 210 connected to the digital twin model 200. Herein, the normal range information may include minimum and maximum values for sensor data of a sensor which operates in a normal environment (i.e., minimum and maximum values corresponding to the normal range). Alternatively, the normal range information may include percentage values corresponding to the normal range.

The reference value setting unit 120 may store the reference value and normal range information for the sensor set by the manager in the reference value table mapped to the digital twin model 200.

Meanwhile, according to a conventional method, sensor data collected from a plurality of sensors connected to a digital twin model is analyzed one by one to determine whether the sensors operate normally based on a result of the analysis. According to the conventional method, when an emergency occurs in a target area, it is difficult to identify a digital twin model connected to a malfunctioning sensor. Even if it is possible to identify a digital twin model connected to a malfunctioning sensor, it is challenging to take swift follow-up actions at a location where the sensor was installed.

However, according to the present disclosure, it is possible to quickly search for a digital twin model connected to a malfunctioning sensor or a sensor that the manager wants to locate by setting a reference value for each sensor, and, thus, the manager can quickly identify the type of disaster occurring at a location where the sensor is installed and receive help to take initial response actions.

Referring back to FIG. 1, the analysis unit 140 may compare and analyze real-time sensor data measured by the selected sensor with a reference value for the selected sensor.

For example, if real-time sensor data is measured by the temperature sensor in summer, the analysis unit 140 may compare and analyze the real-time sensor data of the temperature sensor with a reference value for the temperature sensor corresponding to summer.

For example, if the real-time sensor data is measured by the temperature sensor during the first time slot (00:00 to 06:00), the analysis unit 140 may compare and analyze the real-time sensor data of the temperature sensor with a reference value for the temperature sensor corresponding to the first time slot.

For example, if the real-time sensor data measured by the temperature sensor is 29° C. and the reference value set for the temperature sensor is 25° C., the analysis unit 140 can calculate a difference (i.e., abs (25-29)) between 29° C., which is the real-time sensor data, and 25° C., which is the reference value.

The determination unit 150 may determine whether real-time sensor data measured by a selected sensor is normal based on a result of the comparison between the real-time sensor data of the sensor and a preset reference value.

The analysis unit 140 may calculate a difference between the real-time sensor data and the reference value and analyze whether an absolute value of the calculated difference falls within a normal range calculated based on normal range information.

For example, if the real-time sensor data measured by the temperature sensor is 29° C., the reference value set for the temperature sensor is 25° C. and the normal range percentage set for the temperature sensor is set to +10%, the analysis unit 140 can analyze whether an absolute value of a difference of 4 falls within a normal range of −2.5° C. to +2.5° C.

When an absolute value of the calculated difference falls within the normal range calculated based on the normal range information, the determination unit 150 may determine that the real-time sensor data is normal. Herein, the criterion for normal data may be whether sensor data measured from a target area to be managed is kept within the normal range. Further, when the absolute value of the calculated difference is out of the normal range calculated based on the normal range information, the determination unit 150 may determine that the real-time sensor data is abnormal.

In general, the indoor temperature during the summer is between 18° C. and 25° C. However, for example, when sensor data measured by the temperature sensor from the target area is 70° C., it may be determined that a fire has occurred in the target area.

When there is a plurality of sensors connected to the digital twin model 200, the determination unit 150 may further determine whether the real-time sensor data of each of the plurality of sensors 210 is normal based on the real-time sensor data collected from the plurality of sensors 210 connected to the digital twin model 200.

Meanwhile, if it cannot be determined whether the real-time sensor data of the selected sensor is normal based on a result of analysis through comparison between the real-time sensor data measured by the selected sensor and a primary reference value, the reference value setting unit 120 may receive input of a secondary reference value for the selected sensor from the manager or the reference value recommendation unit 130 may recommend the secondary reference value for the selected sensor to the manager. For example, a situation where it cannot be determined whether real-time sensor data is normal may occur when, based on a result of analysis of a plurality of real-time sensor data measured by the selected sensor and the primary reference value, it is determined that more than a predetermined percentage (e.g., 50%) of the plurality of real-time sensor data measured during a predetermined period of time is out of the normal range and no abnormal signals or abnormal data are detected from other sensors than the selected sensor among the plurality of sensors connected to the digital twin model 200.

The output unit 160 may output a result of determining whether the real-time sensor data measured by the selected sensor is normal.

For example, when it is determined that the real-time sensor data measured in real time by the temperature sensor is normal, the output unit 160 may output a first color (e.g., green), when it is determined that the real-time sensor data is abnormal and requires attention, the output unit 160 may output a second color (e.g., orange), and when it is determined that the real-time sensor data is abnormal and indicates danger, the output unit 160 may output a third color (e.g., red).

For example, when the real-time sensor data of the temperature sensor selected by the manager has a value close to the reference value for the temperature sensor, the output unit 160 may display the color of the digital twin model clearly on the screen of a display device connected to the data normality determination apparatus 10. Alternatively, the output unit 160 may display the color of the digital twin model to be increasingly dull on the screen of the display device connected to the data normality determination apparatus 10 as the real-time sensor data of the temperature sensor is increasingly away from the normal range.

For example, the output unit 160 may output a graph of dynamic changes in the determining whether the real-time sensor data of the selected temperature sensor falls within the normal range over time on the screen of the display device connected to the data normality determination apparatus 10.

When an absolute value of the calculated difference is out of the normal range, the output unit 160 may output a warning message indicating that the real-time sensor data is abnormal on the screen of the display device connected to the data normality determination apparatus 10.

When there is a plurality of sensors connected to the digital twin model 200, the output unit 160 may output a result of determining whether the real-time sensor data of each of the plurality of sensors 210 is normal as well as the name of the sensor. Meanwhile, it would be understood by a person with ordinary skill in the art that each of the collection unit 100, the sensor selection unit 110, the reference value setting unit 120, the reference value recommendation unit 130, the analysis unit 140, the determination unit 150, and the output unit 160 can be implemented separately or in combination with one another.

FIG. 4 is a flowchart showing a method for determining whether data of the digital twin model is normal according to an embodiment of the present disclosure.

Referring to FIG. 4, in a process S401, the data normality determination apparatus 10 sets a reference value for a sensor selected from among a plurality of sensors connected to a digital twin model.

In a process S403, the data normality determination apparatus 10 compares and analyzes the reference value with real-time sensor data measured by the selected sensor.

In a process S405, the data normality determination apparatus 10 determines whether the real-time sensor data is normal based on a result of the analysis.

In a process S407, the data normality determination apparatus 10 outputs a result of determining whether the real-time sensor data is normal.

In the descriptions above, the processes S401 to S407 may be divided into additional processes or combined into fewer processes depending on an embodiment. In addition, some of the processes may be omitted and the sequence of the processes may be changed if necessary.

The embodiment of the present disclosure can be embodied in a storage medium including instruction codes executable by a computer such as a program module executed by the computer. A computer-readable medium can be any usable medium which can be accessed by the computer and includes all volatile/non-volatile and removable/non-removable media. Further, the computer-readable medium may include all computer storage media. The computer storage media include all volatile/non-volatile and removable/non-removable media embodied by a certain method or technology for storing information such as computer-readable instruction code, a data structure, a program module or other data.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A data normality determination apparatus that determines whether data of a digital twin model is normal, comprising:
a reference value setting unit configured to set a reference value for a sensor selected from among a plurality of sensors connected to the digital twin model;
an analysis unit configured to compare and analyze real-time sensor data measured by the selected sensor with the reference value;
a determination unit configured to determine whether the real-time sensor data is normal based on a result of the analysis; and
an output unit configured to output a result of determining whether the real-time sensor data is normal.

2. The data normality determination apparatus of claim 1,
wherein the reference value setting unit is further configured to set normal range information for the selected sensor.

3. The data normality determination apparatus of claim 1,
wherein the reference value includes at least one of seasonal reference values and time-based reference values.

4. The data normality determination apparatus of claim 1, further comprising:
a reference value recommendation unit configured to analyze pattern information based on sensor data previously collected from the selected sensor, derive the reference value based on the analyzed pattern information, and recommend the derived reference value.

5. The data normality determination apparatus of claim 1, further comprising:
a reference value recommendation unit configured to analyze a similarity between a plurality of digital twin models and the digital twin model, select a similar digital twin model from the plurality of digital twin models based on the analyzed similarity, extract a reference value set for at least one sensor related to the selected similar digital twin model, and recommend the extracted reference value.

6. The data normality determination apparatus of claim 2,
wherein the analysis unit is further configured to calculate a difference between the real-time sensor data and the reference value, and analyzes whether an absolute value of the calculated difference falls within a normal range calculated based on the normal range information.

7. The data normality determination apparatus of claim 6,
wherein when the absolute value of the calculated difference falls within the normal range calculated based on the normal range information, the determination unit determines that the real-time sensor data is normal, and
when the absolute value of the calculated difference is out of the normal range calculated based on the normal range information, the determination unit determines that the real-time sensor data is abnormal.

8. The data normality determination apparatus of claim 6,
wherein when the absolute value of the calculated difference is out of the normal range calculated based on the normal range information, the output unit is further configured to output a warning message indicating that the real-time sensor data is abnormal.

9. The data normality determination apparatus of claim 1, further comprising:
if there is a history in which reference values have been set for the selected sensor, a reference value recommendation unit configured to select one of the reference values for the selected sensor based on an absolute value of a difference between the real-time sensor data measured by the selected sensor and reference values for the selected sensor, and recommend the selected reference value.

10. The data normality determination apparatus of claim 1,
wherein if it cannot be determined whether the real-time sensor data is normal based on a result of analysis through comparison between the real-time sensor data measured by the selected sensor and a primary reference value set for the selected sensor, the reference value setting unit is configured to receive input of a secondary reference value for the selected sensor.

11. A method for determining whether data of a digital twin model is normal, which is performed by a data normality determination apparatus, comprising:
setting a reference value for a sensor selected from among a plurality of sensors connected to the digital twin model;
comparing and analyzing real-time sensor data measured by the selected sensor with the reference value;
determining whether the real-time sensor data is normal based on a result of the analysis; and
outputting a result of determining whether the real-time sensor data is normal.

12. A non-transitory computer-readable medium storing a computer program including a sequence of instructions to determine whether data of a digital twin model is normal, which when executed by a computing device, causes the computing device to:
set a reference value for a sensor selected from among a plurality of sensors connected to the digital twin model;
compare and analyze real-time sensor data measured by the selected sensor with the reference value;
determine whether the real-time sensor data is normal based on a result of the analysis; and
output a result of determining whether the real-time sensor data is normal.
